(19) United States
(12) Patent Application Publication
(10) Pub. No.: US 2004/0251047 A1
(43) Pub. Date: Dec. 16, 2004

(54) Via structure for increased wiring on printed wiring boards

(75) Inventors: Gerald Keith Bartley, Rochester, MN (US); Paul Eric Dahlen, Rochester, MN (US); Philip Raymond Germann, Rochester, MN (US); Andrew B. Maki, Rochester, MN (US); Mark Owen Maxson, Mantorville, MN (US)

Correspondence Address: Robert R. Williams, IBM Corporation, Dept. 917, 3605 Highway 52 North, Rochester, MN, 55901-7829, US

(73) Assignee: International Business Machines Corporation, Armonk, NY

(21) Appl. No.: 10/460,591

(22) Filed: Jun. 12, 2003

(51) Int. Cl. H05K 7/06

(52) U.S. Cl. 174/262; 174/266; 29/852

(57) ABSTRACT

Methods and apparatus are disclosed for improved via utilization on printed wiring boards (PWB). A via in a PWB typically transfers a single electrical signal from one signal plane to another wiring plane on the PWB. The present invention provides for more than a single signal to be transferred through a single via having a conducting wall. The conducting wall of the via is divided into more than one conducting portion, each portion capable of conducting a signal from one signal plane to another signal plane.

### BACKGROUND OF THE INVENTION

1. Field of the Invention

The present invention generally relates to printed wiring boards (PWBs), also known as printed circuit boards (PCBs). More particularly, the present invention relates to vias on such boards.

2. Description of the Related Art

Printed wiring boards (PWBs) have long been used to mechanically hold and electrically interconnect electronic components. Transistors, resistors, and capacitors have been soldered into PWBs and interconnected by signal conductors in or on the surfaces of PWBs for many decades. In the 1960's, integrated circuits of many types were placed in modules having a number of pins that were inserted into holes in the PWBs, soldered in place, and interconnected by signal conductors in the PWBs. Today, electronic components such as microprocessors, dynamic random access memories (DRAMs), static random access memories (SRAMs), and application specific integrated circuits (ASICs) are mechanically and electrically coupled to PWBs, and can have hundreds or thousands of electrical connections with signal conductors in, or on, the PWBs.

Signal conductors in or on a PWB interconnect electrical components that are mechanically coupled on the PWB, or to connectors that allow signals to be routed from or to the PWB. Signal conductors will hereinafter be said to be “in” the PWB; those skilled in the art will understand that signal conductors on a top surface or a bottom surface are included. The signal conductors are usually on more than a single signal plane. For example, one or more signal planes have signal conductors predominantly running in a first direction, and one or more signal planes have signal conductors predominantly running in a second direction substantially orthogonal to the first direction. Some PWBs have signal planes where the wiring runs at an angle (usually 45 degrees) to the wiring of the signal planes mentioned above.

Interconnection of electrical components usually requires that individual signal conduction paths change direction during the length of their route. For example, to interconnect a particular signal from a particular pin on a first component to a particular pin on a second component might require the signal to travel five centimeters “east”, and three centimeters “north”. A via (a vertical interconnection between one wiring plane of the PWB to another wiring plane) is typically required for such an interconnection to take the signal from an “east-west” signal plane to a “north-south” signal plane. A via is a hole penetrating the entire thickness of the PWB, or, in some cases, a portion of the thickness of the PWB. After creation (by drilling, etching, or other known technique), the hole is plated with an electrically conducting material. The exemplary signal on the “east-west” signal plane is routed to the via location, as is the continuing portion of the exemplary signal on the “north-south” signal plane. When the plating occurs, the two portions of the exemplary signal are electrically coupled.

Provision must be made to ensure that voltage supply planes in the PWB do not come into electrical contact with any electrically conducting material of a via that is used to interconnect a signal from one signal wiring plane to another. This is done by etching away the voltage plane electrical conducting material in the vicinity of a via used to provide signal plane transfers for signals. Multiple voltage planes of the same voltage (e.g., multiple ground planes) are coupled using many vias so that power can flow from one plane to another and so signal return currents can flow closely to signal conductors carrying high-speed signals.

Modern electronic systems have an increasingly large number of signals that must be routed, driving technologists to provide more signal planes on PWBs, as well as producing thinner signal conductors in order to provide more signal conductors in a given area. Use of additional signal planes typically requires more vias. Each via takes up a significant amount of area on the PWB, so minimizing the number of vias is important.

Furthermore, the extremely high-speed data transmission used in modern electronic systems frequently employs differential signal transmission, requiring two signal conductors (i.e., a signal conductor for a true signal phase and a signal conductor for a complement signal phase) for a single logical signal. In differential signaling, some or all of the return signal is by way of the complementary signal conductor, making it important that the two phases of the differential signal be physically close together for their entire route; furthermore, it is very important that the true and complement signal phases be routed on signal conductors having very close to the same physical length. Routing the true and the complement signal conductors through separate, spaced, vias causes a return path discontinuity, as well as making the task of keeping the physical lengths of the true and complement signal conductors similar much more difficult.

Therefore, a need exists for method and apparatus capable of improving the utilization of vias in PWBs, as well as to provide a mechanism to enhance the signal integrity of differential signals by eliminating coupling discontinuities between the true and complement phases of differential signals.

### SUMMARY OF THE INVENTION

The present invention provides for providing signal plane transfers for more than a single signal, using only a single via. The present invention therefore reduces the number of vias required to interconnect electronic components on a PWB. The present invention also improves signal integrity of high-speed differential signals and facilitates length matching of true and complement differential signal conductors.

The drawings and description below uses cylindrical holes in the PWB for vias for exemplary purposes. This is done for simplicity of explanation. Those skilled in the art will understand that vias can be square, rectangular, elliptical, or other shape. In particular, to generalize the conductor coating the via, the conductor is called a conducting via wall. Furthermore, while PWBs are used for exemplary purposes, any carrier of signal conductors having via structures, including but not limited to modules, and cables, is to be considered within the scope of this invention.

In an embodiment, a via having a via wall of electrically conducting material is created; the via wall is divided into a plurality of electrically isolated via wall regions; each region coupling a separate signal conductor from one wiring plane to another wiring plane.

In an embodiment, a via wall of electrically conducting material is partitioned into a plurality of electrically isolated via wall regions by drilling two or more holes substantially parallel with the axis of the via, the drill removing portions of the via wall.

In an embodiment, a via wall of electrically conducting material is partitioned into a plurality of electrically isolated via wall regions by mechanically cutting the via wall.

In an embodiment, a via wall of electrically conducting material is partitioned into a plurality of electrically isolated via wall regions by masking and chemical etching.

In yet another embodiment, a true and a complement signal conductor is routed from a first signal plane to a second signal plane through electrically isolated via wall regions of the same via.

### BRIEF DESCRIPTION OF THE DRAWINGS

So that the manner in which the above recited features, advantages and objects of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1A shows a top view of a prior art via in which a single signal is routed from a first wiring plane to a second wiring plane.

FIG. 1B shows an isometric view of a prior art via in which a single signal is routed from a first wiring plane to a second wiring plane.

FIG. 2A shows a top view of a via divided into electrically isolated parts, each part routing a signal from a first wiring plane to a second wiring plane.

FIG. 2B shows an isometric view of a conducting via wall divided into electrically isolated parts, each part routing a signal from a first wiring plane to a second wiring plane.

FIG. 3 shows a laser ablation of a conducting via wall dividing the via wall into electrically isolated parts.

FIG. 4A shows an isometric view of a tool suitable to cut a conducting via wall into two electrically isolated parts.

FIG. 4B shows a top view of a tool suitable to cut a conducting via wall into two electrically isolated parts.

FIG. 4C shows a top view of a conducting via wall after being cut by the tool shown in FIGS. 4A and 4B.

FIG. 5A an isometric view of a tool suitable to cut a conducting via wall into four electrically isolated parts.

FIG. 5B shows a top view of a tool suitable to cut a conducting via wall into four electrically isolated parts.

FIG. 5C shows a top view of a conducting via wall after being cut by the tool shown in FIGS. 5A and 5B.

FIG. 6A shows an isometric view of a plug having ridges, the distance between the outer ends of the ridges being substantially equal to the inside diameter of the electrically conducting via wall.

FIG. 6B shows an isometric view of the plug, having resist material coating the entire plug except the outer ends of the ridges and the top and bottom of the plug, being inserted into an electrically conducting via wall.

FIG. 6C shows a top view of the via wall of FIG. 6B after the resist material has been deposited on the inner portion of the via wall.

FIG. 6D shows a top view of the via wall of FIG. 6C after an etching process has removed portions of the electrically conducting via wall, dividing the electrically conducting via wall into two via wall portions.

FIG. 6E shows a top view of the via wall of FIG. 6D after the resist material has been removed from the two via wall portions.

FIG. 7A shows a cross section of a Printed Wiring Board and a via that has been divided into two electrically isolated portions, each portion transferring a separate signal from a first signal plane to a second signal plane.

FIG. 7B shows a cross section of a Printed Wiring Board and a via that has been divided into two electrically isolated portions, a first portion transferring a first signal from a first signal plane to a second signal plane, the second portion transferring a second signal from a first signal plane to a third signal plane.

FIG. 7C shows a cross section of a Printed Wiring Board and a via that has been divided into two electrically isolated portions, a first portion transferring a first signal from a first signal plane to a second signal plane, the second portion transferring a second signal from a third signal plane to a fourth signal plane.

FIG. 8 is a flow chart showing, at a high level, a method of transferring more than one signal from one signal plane to another using the same via.

### DETAILED DESCRIPTION OF THE PREFERRED EMBODIMENTS

The present invention provides for allowing signal plane transfers for more than a single signal using a single via.

The drawings and description below uses cylindrical holes in the PWB for vias for exemplary purposes. This is done for simplicity of explanation. Those skilled in the art will understand that vias can be square, rectangular, elliptical, or other shape. Terms used that refer to a cylinder or cylinder are intended to also apply to the corresponding counterpart of vias having a shape other than cylindrical. In particular, to generalize the conductor coating the via, the conductor is called a conducting via wall. Furthermore, while PWBs are used for exemplary purposes, any carrier of signal conductors having via structures, including, but not limited to, modules and cables, is to be considered within the scope of this invention.

The via comprises an electrically conducting via wall that is divided into N electrically isolated portions, each portion capable of transferring a signal from one signal plane in the PWB to another signal plane in the PWB. For example, where N=2, the conducting via wall is bifurcated, and a first signal is routed from a first wiring plane to a second wiring plane using a first conducting portion of the bifurcated conducting via wall. A second signal is routed from the first wiring plane to the second wiring plane using a second conducting portion of the bifurcated conducting via wall. Since the first and second conducting portions of the bifurcated conducting via wall are electrically isolated, the first signal is not short circuited to the second signal. The present invention is particularly advantageous to maintain coupling between the first signal and the second signal when the first and second signals are a true signal and a complement signal components of a differential signal.

Having reference now to the figures, and having provided above a discussion of the art, the present invention will be described in detail.

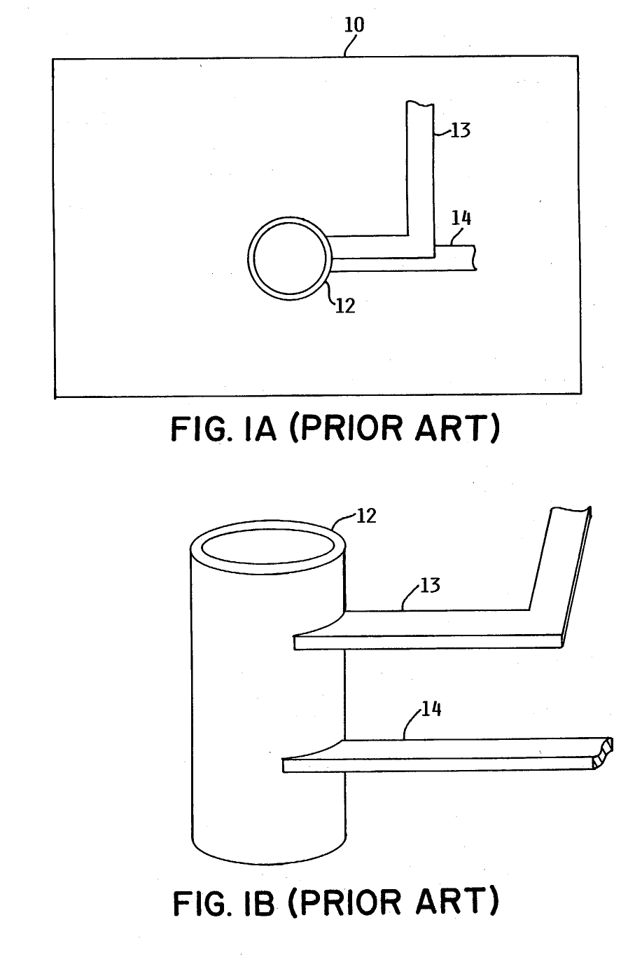

FIG. 1A shows a prior top view of a printed wiring board, PWB 10, having a via comprising an electrically conducting via wall 12. A via is made in a PWB by drilling or punching a hole in the PWB. Electrically conducting via wall 12 is made by coating the bore of the hole with an electrically conducting material. Copper is often used as the electrically conducting material, but any suitable electrically conducting material may be used. Signal conductor 13 is an electrically conducting material (e.g., copper) routed to the via and making electrical contact with electrically conducting via wall 12. Signal conductor 14 is similarly shown to be routed to the via and is also in electrical contact with electrically conducting via wall 12. FIG. 1A shows a portion of signal conductor 14 obscured, indicating that it is physically below signal conductor 13, as is better shown in FIG. 1B. Signal conductors 13 and 14 are shown to be routed to conducting via wall 12 substantially horizontally (e.g., from the “east”), however, in other embodiments, signal conductors are routed to conducting via wall 12 at other angles. Furthermore, in embodiments, signal conductor 13 and signal conductor 14 are not routed to conducting via wall 12 at the same angle.

FIG. 1B is an isometric view of electrically conducting via wall 12 and signal conductors 13 and 14. For simplicity, PWB 10 is not shown in FIG. 1B. Electrically conducting via wall 12 typically extends from a top surface of PWB 10 to a bottom surface of PWB 10, however, the present invention contemplates a via with an electrically conducting via wall 12 that does not extend through the entire thickness of PWB 10. PWB 10 comprises two or more signal planes. PWB 10 typically also has voltage supply planes that supply voltages to circuits mounted on PWB 10. An electrical signal is transmitted on signal conductor 13, is routed “downwards” on electrically conducting via wall 12, and continues on signal conductor 14, transferring the signal from a first signal plane to a second signal plane.

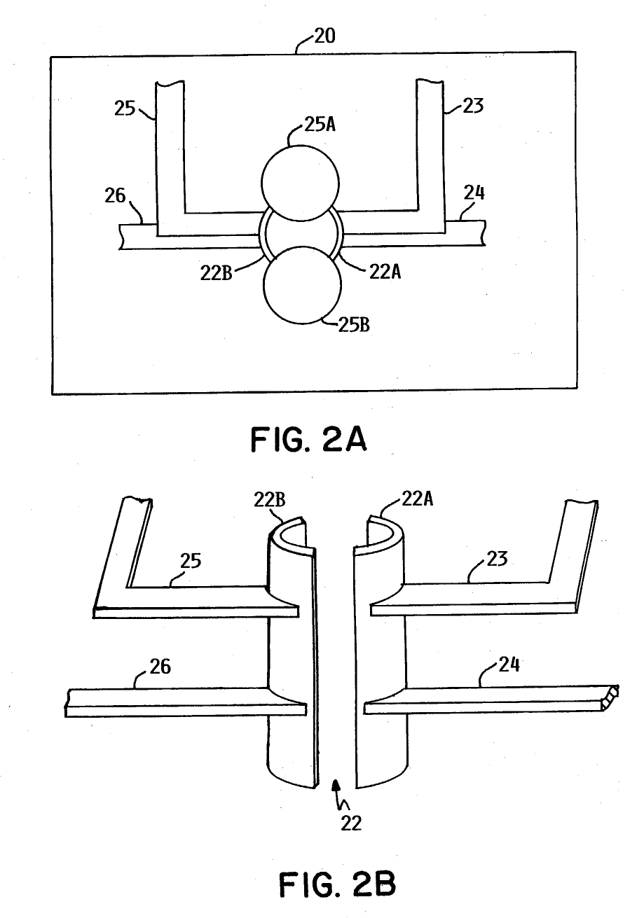

FIG. 2A shows a top view of PWB 20. An electrically conducting via wall has been divided into two electrically conducting via wall portions 22A and 22B. Portions 22A and 22B are electrically isolated. The electrically conducting via wall has been divided into isolated electrically conducting via wall portions 22A and 22B by drilling two holes, hole 25A and hole 25B, the drilling operation removing electrically conducting material from the via wall. Since electrically conducting portions 22A and 22B are electrically isolated from each other, portion 22A is used to couple signal conductor 23 to signal conductor 24; similarly, portion 22B is used to couple signal conductor 25 to signal conductor 26. Holes 25A and 25B are of small enough diameter not to interfere with signal wiring on the PWB.

FIG. 2B shows an isometric view of an electrically conducting via wall 22 that has been separated into electrically isolated via wall portions 22A and 22B. The remainder of PWB 20 is not shown, in order to simplify the drawing. Signal conductor 23 is coupled to signal conductor 24 by portion 22A; signal conductor 25 is coupled to signal conductor 26 by portion 22B. Signal conductors are routed to portions 22A and 22B at any angle that allow suitable electrical connections to be made with portions 22A and 22B.

The present invention contemplates any method embodiment that separates an electrically conducting via wall of a via in a PWB into more than one electrically isolated via wall portions.

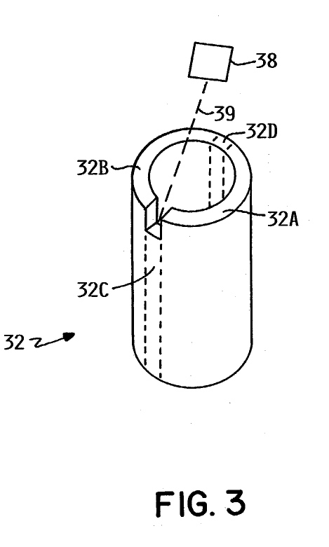

In an embodiment illustrated in FIG. 3, a laser 38 is shown being used to separate electrically conducting via wall 32 into via wall portions 32A and 32B by laser ablation of electrically conducting material along channels 32C and 32D. Laser 38 is chosen to be of sufficient power as to ablate the electrically conducting material. Laser 38 may emit an ablating beam directly down, that is, parallel to the axis of via wall 32, or may be moved slightly to the side, allowing beam 39 to reach channels 32C and 32D partially within the barrel of via wall 32. Having laser 38 moved slightly to the side facilitates ablating channels 32C and 32D such that they are not simply straight “cuts” parallel to the axis of the via; for example, channels 32C and 32D can be rotated about an axis of the via to facilitate transfer of signals from one plane to another. A spiral, similar to a barber pole, could be used to rotate via wall portions 32A and 32B. For example, if via wall portions 32A and 32B are transferring signals from a “north-south” wiring plane to an “east-west” wiring plane, a 90 degree “spiral” in the shapes of 32A and 32B would facilitate such a transfer. The rotation, in embodiments, rather than running channels 32C and 32D in spiral, “barbershop-pole-like”, paths, is accomplished by running channels 32C and 32D substantially parallel with the axis of the via for a portion of the length of the via wall, then running channels 32C and 32D for a portion of the circumference of the via wall.

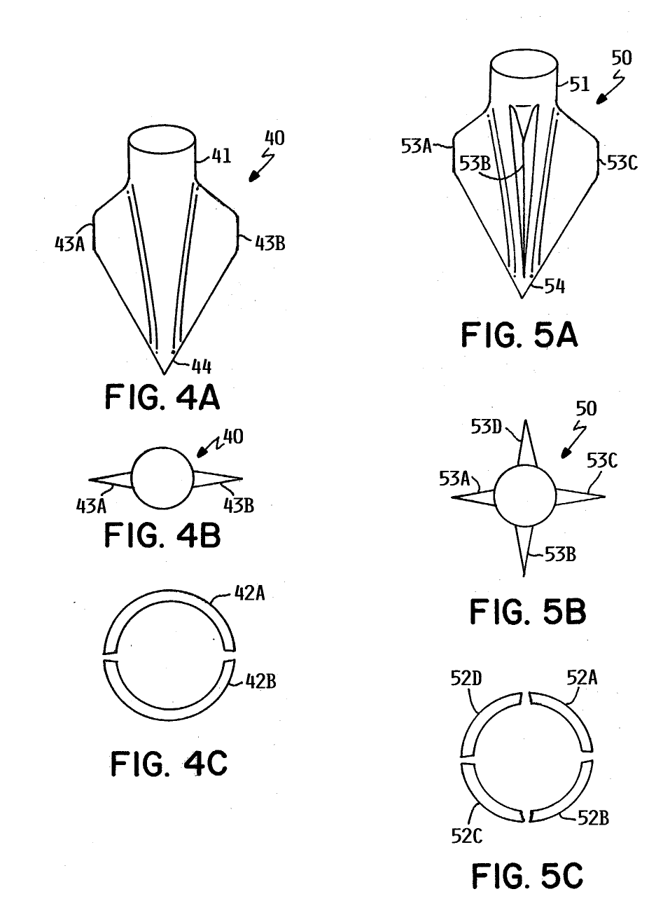

The electrically conducting via wall of the via is mechanically cut in embodiments, illustrated in FIGS. 4A-4C and 5A-5C.

FIG. 4A shows an isometric view of a tool suitable to cut an electrically conducting via wall into two isolated via wall portions. A “cut” is used here to mean electrically isolating one portion of the conducting via wall from another portion of the conducting via wall. Tool 40 has a shaft 41 suitable for gripping by a driving tool (not shown) that is capable of driving tool 40 into a conducting via wall. Tool 40 has blades 43A and 43B which are sharp enough to cut an electrically conducting via wall, and having two blades, makes two “cuts”. Tool 40 has a tapered end 44 suitable to provide alignment and centering as tool 40 is driven into the electrically conducting via wall. FIG. 4B shows a top view of tool 40, illustrating an exemplary shape of blades 43A and 43B. FIG. 4C shows an electrically conducting via wall that has been divided into isolated via wall portions 42A and 42B by tool 40. Similarly, FIG. 5A shows tool 50, having a shaft 51, a tapered end 54, and blades 53A, 53B, 53C, and 53D. Tool 50 is shown in top view in FIG. 5B to better show blades 53A, 53B, 53C, and 53D. Having four blades, tool 50 makes four “cuts” in the electrically conducting via wall. FIG. 5C shows an electrically conducting via wall divided into four isolated via wall portions 52A, 52B, 52C, and 52D. Each isolated via wall portion is capable of transferring a signal from one signal plane to another signal plane. In embodiments where the conducting via wall portions are rotated about the axis of the via, the blades (e.g., blades 43A and 43B, or blades 53A, 53B, 53C, and 53D), are formed at an angle on the tool, similar to a thread on a screw, to cut the via wall into helix-shaped conducting via wall portions.

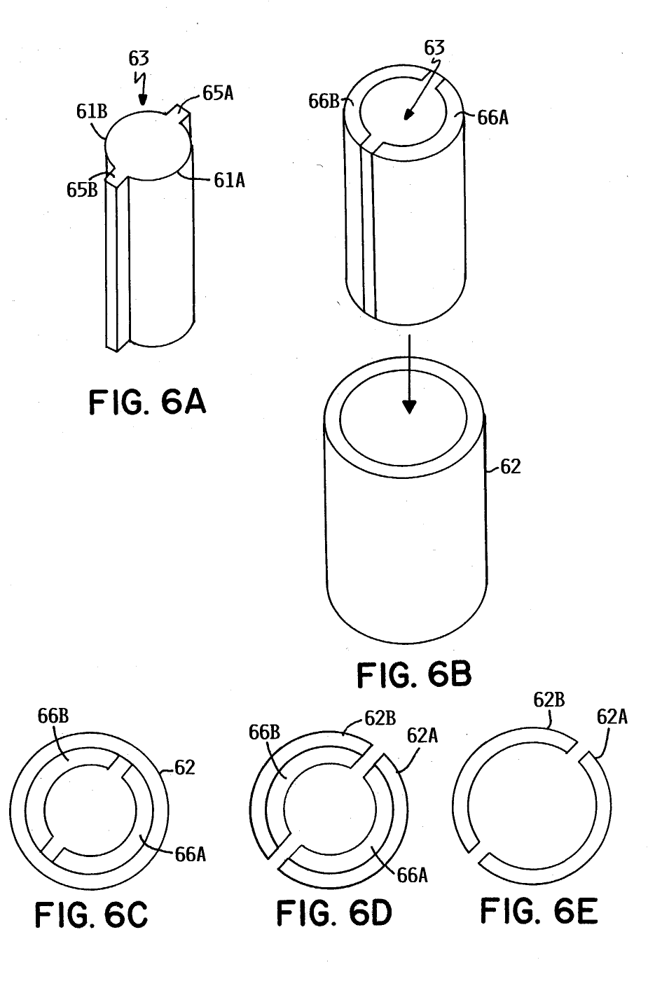

In yet another embodiment, the electrically conducting via wall of the via is chemically etched into two or more electrically isolated via wall portions as illustrated in FIGS. 6A-6E.

FIG. 6A shows a plug 63 having ridges 65A and 65B. Plug 63 also has a small portion comprising wall 61A and wall 61B. Ridges 65A and 65B are substantially the same diameter as the inside diameter of an electrically conducting via wall of a via. FIG. 6B shows plug 63 coated with a layer of resist material adhering to walls 61A and 61B of plug 63 and not extending further out, radially, than the outer ends of ridges 65A and 65B, resulting in resist portions 66A and 66B. The composite structure of plug 63, ridges 65A and 65B, and resist portions 66A and 66B is of substantially the same diameter as the inner diameter of the electrically conducting via wall of a via. As shown in FIG. 6B, the composite structure is inserted into electrically conducting via wall 62. Resist portions 66A and 66B are transferred to the inner surface of electrically conducting via wall 62 as shown in FIG. 6C by heating and/or inherent adhesion properties of the resist material. The resist material is suitably not affected by an etchant which is applied and which etches those portions of electrically conducting via wall 62 not masked by resist portions 66A and 66B, thus electrically isolating via wall portions 62A and 62B from each other. In a final step, the resist material is removed, as shown in FIG. 6E. Although only two electrically isolated via wall portions are shown in FIGS. 6A-6E, more ridges than just 65A and 65B are contemplated in embodiments, creating additional electrically isolated via wall portions. Those skilled in the art will recognize that the top and bottom surfaces of electrically conducting via wall 62 must be also coated with resist in order to prevent the etchant from acting upon those surfaces. Those skilled in the art will also understand that variants of the process described are contemplated, including “negative resist” processes in which several resists are used, and a first resist defines areas on the inner surface of electrically conducting via wall 62 that are not to be etched, rather than defining areas that will be etched. Although ridges 65A and 65B are shown to be straight, in other embodiments they are designed to “spiral” or otherwise rotate, creating electrically conducting via wall portions that also spiral or rotate about an axis of the via. Such spiral conductors facilitate signal plane transfers as described earlier, in many wiring situations (e.g., transferring signals from an “east-west” signal wiring plane to a “north-south” signal wiring plane).

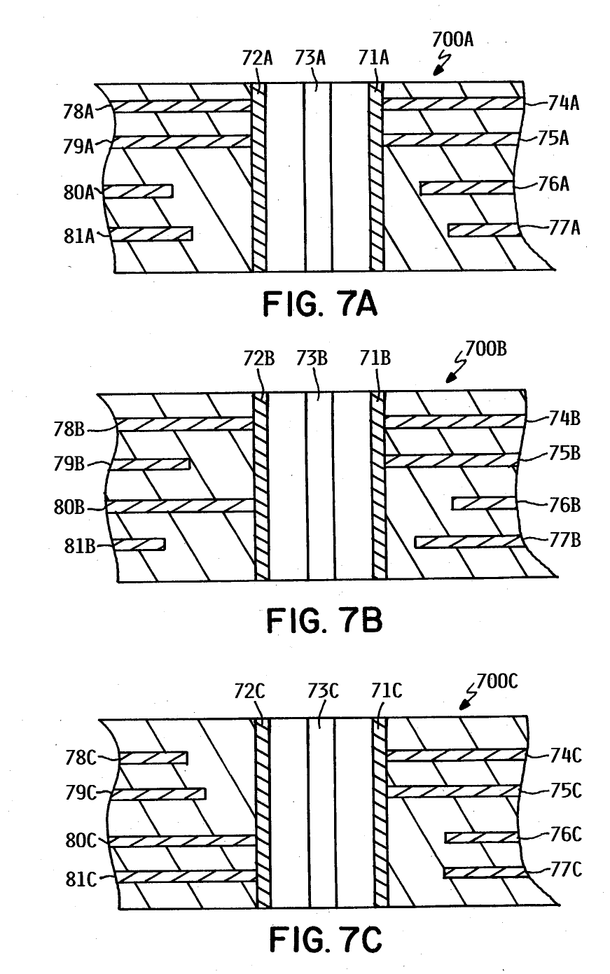

FIGS. 7A-7C show several signal plane transfer combinations that can be accomplished by the present invention. These figures are exemplary only, and for simplicity only show two signals having signal plane transfers.

FIG. 7A shows a cross section of a PWB generally shown as 700A and two electrically isolated via wall portions. A first electrically isolated via wall portion 71A is shown to couple signal conductor 74A from a first signal plane to signal conductor 75A on a second signal plane. Gap 73A is a “gap” that electrically isolates first electrically isolated via wall portion 71A from a second electrically isolated via wall portion 72A. Second electrically isolated via wall portion 72A is shown coupling signal conductor 78A from the first signal plane to the second signal plane. Signal conductors 76A and 80A are on a third signaling plane but are not coupled to either first or second via wall portion 71A or 72A. Signal conductors 76A and 80A are illustrated only to show that additional signal planes exist in some embodiments, but which are not coupled to any via wall portion in the via. Similarly, signal conductors 77A and 81A show a fourth signal plane with signal conductors.

FIG. 7B shows a cross section of a PWB generally shown as 700B and two electrically isolated via wall portions. A first electrically isolated via wall portion 71B is shown to couple signal conductor 74B from a first signal plane to signal conductor 75B on a second signal plane. Gap 73B is a “gap” that electrically isolates first electrically isolated via wall portion 71B from a second electrically isolated via wall portion 72B. Second electrically isolated via wall portion 72B is shown coupling signal conductor 78B from the first signal plane to a third signal plane. Signal conductors 76B, 77B, 79B and 81B are shown only to illustrate additional signal wiring that may exist on signal planes in PWB 700B.

FIG. 7C shows a cross section of a PWB generally shown as 700C and two electrically isolated via wall portions. A first electrically isolated via wall portion 71C is shown to couple signal conductor 74C from a first signal plane to signal conductor 75C on a second signal plane. Gap 73C is a “gap” that electrically isolates first electrically isolated via wall portion 71C from a second electrically isolated via wall portion 72C. Second electrically isolated via wall portion 72C is shown coupling signal conductor 78B from a third signal plane to a fourth signal plane. Signal conductors 76C, 77C, 78C and 79C are shown only to illustrate additional signal wiring that may exist on signal planes in PWB 700C.

Although several exemplary signal plane transfers have been specifically given above, those skilled in the art will understand that, in embodiments, a via wall portion provides signal plane transfers to any signal plane that the via wall portion passes where a signal conductor is routed to the via wall portion. A via wall portion can couple a particular signal on more than two signal planes. For example, in the example PWB 700C, the first signal could be transferred to conductors 76C and 77C if those conductors were to be routed to via wall portion 71C.

Although in the exemplary signal plane transfer descriptions above all via wall portions are used to make signal plane transfers, some via wall portions may be unused. For example, if four via wall portions are created, a user may choose to only use three of the via wall portions to make signal plane transfers, leaving the fourth via wall portion unconnected.

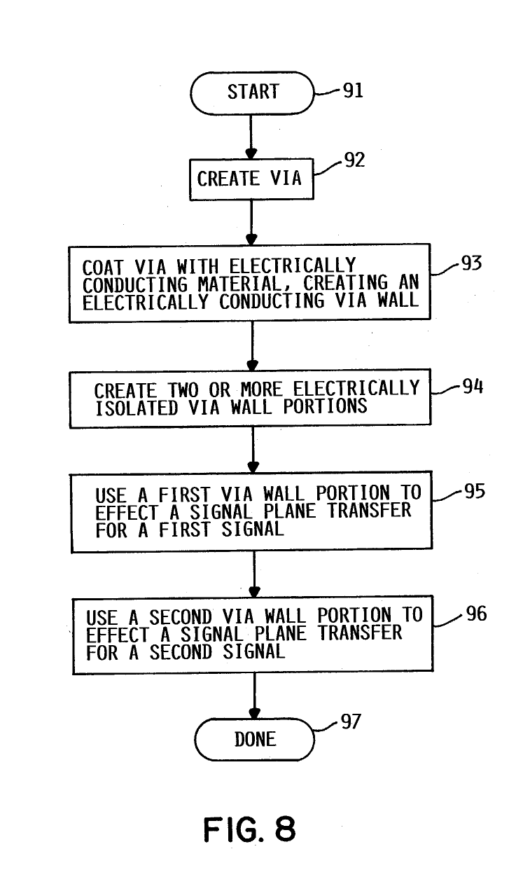

In an embodiment, a via wall portion unused by signals is coupled to two or more voltage planes of the same voltage. Coupling a via wall portion to more than one voltage plane of the same voltage (e.g., ground) is advantageous in providing a closely-coupled signal return path for a signal that is transferred from one signal plane to another using another via wall portion in the same via. In yet another embodiment, a first via wall portion couples two or more voltage planes of a first voltage (e.g., ground), and a second via wall portion couples two or more voltage planes of a second voltage (e.g., Vdd).

Whereas various embodiments of the method have been described in detail above, FIG. 8 is a high level flow chart that illustrates the method at a high level.

Step 91 begins the process.

In step 92, a via is created by drilling, punching, or other methods of producing vias.

In step 93, the via is coated with an electrically conducting material, forming an electrically conducting via wall. As stated before, the electrically conducting material can be copper or other suitable electrically conducting material.

In step 94, the electrically conducting via wall is divided into two or more electrically isolated via wall portions by drilling, laser ablation, cutting, or chemical etching.

In step 95, a first via wall portion is used to make a signal plane transfer for a first signal.

In step 96, a second via wall portion is used to make a signal plane transfer for a second signal.

It will be understood that further steps similar to steps 95 and 96, in embodiments having more than two via wall portions, are performed to make signal plane transfers for additional signals.

While the foregoing is directed to embodiments of the present invention, other and further embodiments of the invention may be devised without departing from the basic scope thereof, and the scope thereof is determined by the claims that follow.

What is claimed is:

1. A method for providing a signal plane transfer for more than a single electrical signal, using a single via, on a carrier of signal conductors having more than a single signal plane, comprising the steps of:
creating the via in the carrier of signal conductors;
creating an electrically conducting via wall by coating the via with electrically conducting material;
creating two or more electrically isolated portions of the conducting via wall; and
providing signal plane transfers for two or more electrical signals, each of the signals using a separate instance of the two or more electrically isolated portions of the conducting via wall to accomplish the signal plane transfer.

2. The method of claim 1, further comprising the step of providing a rotation about an axis of the via for at least one of the electrically isolated portions of the conducting via walls between a first signal plane and a second signal plane.

3. The method of claim 1, the step of creating two or more electrically isolated portions of the conducting via wall further comprising using laser ablation to create the two or more electrically isolated portions of the conducting via wall.

4. The method of claim 3, the step of using laser ablation to create the two or more electrically isolated portions of the conducting via wall further comprising the step of ablating all the electrically conducting material from a top of the conducting via wall to a bottom of the via wall along as many lines as the number of electrically isolated portions of the conducting via wall that are created.

5. The method of claim 1, the step of creating two or more electrically isolated portions of the conducting via wall further comprising the step of drilling N holes, each hole removing a section of conducting material from the via wall from a top of the via wall to the bottom of the via wall, where N is the number of electrically isolated portions of the conducting via wall.

6. The method of claim 1, the step of creating two or more electrically isolated portions of the conducting via wall further comprising the step of mechanically making N cuts in the conducting via wall, where N is the number of electrically isolated portions of the conducting via wall.

7. The method of claim 1, the step of creating two or more electrically isolated portions of the conducting via wall further comprising the step of chemically etching N regions in the conducting via wall, where N is the number of electrically isolated portions of the conducting via wall.

8. The method of claim 7, further comprising the steps of:
inserting a plug having a pattern of resist material into the via, the pattern defining N regions covered with the resist material and N regions lacking the resist material;
transferring the pattern of resist material from the plug to the conducting via wall;
removing the plug from the via;
chemically etching completely through the conducting via wall in the regions lacking the resist material; and
removing the resist material from the conducting via wall.

9. The method of claim 1, the step of providing signal plane transfers for two or more electrical signals comprising the steps of:
transferring a true signal of a differential signal on a first electrically isolated portion of the conducting via wall from a first signal plane to a second signal plane; and
transferring a complement signal of a differential signal on a second electrically isolated portion of the conducting via wall from the first signal plane to the second signal plane.

10. The method of claim 1, the step of providing signal plane transfers for two or more electrical signals comprising the steps of:
transferring a first signal from a first signal plane to a second signal plane via a first electrically isolated portion of the conducting via wall; and
transferring a second signal from the first signal plane to the second signal plane via a second electrically isolated portion of the conducting via wall.

11. The method of claim 1, the step of providing signal plane transfers for two or more signals comprising the steps of:
transferring a first signal from a first signal plane to a second signal plane via a first electrically isolated portion of the conducting via wall; and
transferring a second signal from the first signal plane to a third signal plane.

12. The method of claim 1, the step of providing signal plane transfers for two or more signals comprising the steps of:
transferring a first signal from a first signal plane to a second signal plane; and
transferring a second signal from a third signal plane to a fourth signal plane.

13. A carrier of signal conductors having more than a single signal plane comprising:
a via further comprising more than one electrically conducting via wall portions, each electrically conducting via wall portion being electrically isolated from all other electrically conducting via wall portions in the via.

14. The carrier of signal conductors of claim 13, at least one of the electrically conducting via wall portions being rotated about an axis of the via between a first signal plane and a second signal plane.

15. The carrier of signal conductors of claim 13, wherein each of the more than one electrically conducting via wall portions makes a signal plane transfer of a separate signal.

16. The carrier of signal conductors of claim 13, wherein the number of via wall portions is four, and wherein each of three of the via wall portions make a signal plane transfer of a separate signal.

17. The carrier of signal conductors of claim 13, the carrier of signal conductors further comprising:
a first signal transferred from a first signal plane to a second signal plane using a first of the more than one electrically conducting via wall portions; and
a voltage supply transferred from a first voltage plane to a second voltage plane of the same voltage using a second of the electrically conducting via wall portions.

18. The carrier of signal conductors of claim 13, the carrier of signal conductors further comprising:
a first signal transferred from a first signal plane to a second signal plane using a first of the more than one electrically conducting via wall portions; and
a second signal transferred from the first signal plane to the second signal plane using a second of the more than one electrically conducting via wall portions.

19. The carrier of signal conductors of claim 13, the carrier of signal conductors further comprising a first signal transferred from a first signal plane to a second signal plane using a first of the more than one electrically conducting via wall portions; and
a second signal transferred from the first signal plane to a third signal plane using a second of the more than one electrically conducting via wall portions.

20. The carrier of signal conductors of claim 13, the carrier of signal conductors further comprising a first signal transferred from a first signal plane to a second signal plane using a first of the more than one electrically conducting via wall portions; and
a second signal transferred from a third signal plane to a fourth signal plane using a second of the more than one electrically conducting via wall portions.

21. The carrier of signal conductors of claim 13, the carrier of signal conductors further comprising:
a differential signal having a true phase signal and a complement phase signal;
the true phase signal being transferred from a first signal plane using a first of the more than one electrically conducting via wall portions; and
the complement phase signal being transferred from the first signal plane using a second of the more than one electrically conducting via wall portions.

22. The carrier of signal conductors of claim 13, the carrier of signal conductors further comprising:
a first voltage plane having a first voltage being coupled to one or more other voltage planes of the first voltage using a first of the more than one electrically conducting via wall portions; and
a second voltage plane having a second voltage being coupled to one or more other voltage planes of the second voltage using a second of the more than one electrically conducting via wall portions.

23. The carrier of signal conductors of claim 13, wherein at least one of the signal plane transfers of the separate signals transfers a particular separate signal from a first signal plane to two or more other signal planes.
